(19) United States
(12) Patent Application Publication
(10) Pub. No.: US 2021/0405093 A1
(43) Pub. Date: Dec. 30, 2021

(54) CORELESS CONTACTLESS CURRENT MEASUREMENT SYSTEM

(71) Applicants: Ki Chul HONG, Yongin-Si, Gyeonggi-do (KR); Ki Seok KIM, Yongin-Si, Gyeonggi-do (KR); EPT CO., INC., Pohang-Si, Gyeongsangbuk-do (KR); POSTECH ACADEMY-INDUSTRY FOUNDATION, Pohang-si, Gyeongsangbuk-do (KR)

(72) Inventors: Ki Chul HONG, Yongin-Si, Gyeonggi-do (KR); Ki Seok KIM, Yongin-Si, Gyeonggi-do (KR); Kwang Hee NAM, Pohang-Si, Gyeongsangbuk-do (KR)

(21) Appl. No.: 17/271,188

(22) PCT Filed: Aug. 23, 2019
(86) PCT No.: PCT/KR2019/010757

§ 371 Date: Sep. 9, 2021

(30) Foreign Application Priority Data
Aug. 24, 2018 (KR) 10-2018-0099005

(51) Int. Cl. G01R 15/18; H01F 17/02

(52) U.S. Cl. CPC G01R 15/181; H01F 17/02

(57) ABSTRACT

The present invention provides a careless contactless current measurement system comprising a conductive means through which a current can flow and a current sensor for calculating information about the current flowing through the conductive means, wherein: a relative position between at least a part of the conductive means and at least a part of the current sensor is fixed; the current sensor obtains a magnetic flux generated by the current flowing through the conductive means and transmitted through a nonmagnetic material, and outputs information about the current flowing through the conductive means in a wired or wireless manner Because such characteristics change only the shape of the conductive means around the magnetic flux measuring means without using a magnetic core, the amount of a magnetic flux passing through the magnetic flux measuring means is increased, thereby improving a signal-to-noise ratio (SNR) of the magnetic flux measuring means.

### CROSS REFERENCE TO RELATED APPLICATIONS

The present application is a U.S. National Phase of International Application No. PCT/KR2019/010757, entitled “CORELESS CONTACTLESS CURRENT MEASUREMENT SYSTEM”, and filed on Aug. 23, 2019. International Application No. PCT/KR2019/010757 claims priority to Korean Patent Application No. 10-2018-0099005 filed on Aug. 24, 2018. The entire contents of the above-listed applications are hereby incorporated by reference for all purposes.

### TECHNICAL FIELD

The present disclosure relates to a current measurement system, and more specifically, to a system for measuring a current flowing through a conductor in a non-contact manner without having a magnetic core.

### BACKGROUND AND SUMMARY

A non-contact current sensor is typically a Hall sensor including a magnetic core and a Hall element (magnetic flux measurement unit). FIG. 1 shows an example of the prior art. A magnetic core 2 has a circular or annular shape, and a portion thereof is cut to have an air gap. A Hall element (magnetic flux measurement unit 3) is installed in the air gap and installed in a sensor body together with the magnetic core. When the Hall element of the Hall sensor is installed near a conductive member in which an electric current flows, a magnetic field generated by the current is concentrated on the magnetic core to increase a magnetic flux density, and the increased magnetic flux penetrates the Hall element, so that the Hall element generates a voltage due to a Hall effect corresponding to the magnetic flux. The voltage may be converted into a current, thus measuring the current. An ideal Hall element outputs a Hall voltage proportional to a surrounding magnetic field when a constant current source is applied. As described above, the current sensor using the magnetic core and the Hall element is widely used, and this method is called an open-loop current transducer.

To this end, since a magnetic core is manufactured using a material of silicon-steel and nickel-alloy, or ferrite, the magnetic core has high permeability compared with air. First, a toroidal-shaped magnetic core is manufactured and cut to form an air gap, and then a Hall element is mounted in the air gap. Thereafter, when a conducting wire is installed to penetrate the center of the magnetic core and a current flows through the conducting wire, a magnetic field proportional to the current is generated around the conducting wire. The magnetic field passing through the magnetic core is much larger than air of a magnetic flux density penetrating the air gap due to high permeability of the magnetic core. Thus, a sufficient Hall voltage is generated from the Hall element, so that a current value may be indirectly known. That is, the magnetic flux induced by the current flowing through the conducting wire to be measured is effectively concentrated in the magnetic core to thereby increase the magnetic flux density, so that the current value of the conducting wire to be measured may be measured relatively accurately.

However, permeability of the magnetic core is changed according to temperatures, so that linearity of a magnetic flux density versus the current value is bad. In order to prevent saturation of the magnetic flux density, a volume of the magnetic core should be increased as the amount of current increases, and thus, a weight, a volume, and a size of the current sensor cannot be reduced. Furthermore, a price of a material cost of the magnetic core in a total price of the current sensor is so high to become a major obstacle in lowering the price of the current sensor.

Recently, multiple current sensors are applied to automobiles including eco-friendly vehicles, and, compared with current sensors for an industrial use, requirements of vehicle parts are more severe in terms of weight, volume, size, price, reliability, vibration resistance, operating temperature range, measurement accuracy and precision, and in this sense, the aforementioned Hall sensor of the prior art needs to be improved. Specifically, problems that may arise in application of the Hall sensor of the prior art to vehicles are as follows. \hat{1} A weight of a vehicle component has a direct effect on vehicle fuel efficiency, so the weight of the component should be reduced, but the current sensor is heavy due to the weight of the magnetic core. \hat{2} A size of components should be reduced in that parts are to be installed in a limited space of a vehicle and space for a user is secured to be as large as possible to improve marketability of the vehicle, but a minimum volume of the magnetic core is determined according to the range of a measurement current and the volume of the magnetic core occupies most of the volume of the current sensor, which is a large obstacle to reducing the volume of the current sensor. \hat{3} A material cost of each component needs to be lowered according to mass-production of vehicles; however, since the price of the magnetic core has a large share of the price of the current sensor, there is a limitation in lowering the price of the current sensor. \hat{4} Unlike industrial applications in which an ambient temperature is maintained within an appropriate range (0 to 40 degrees), an ambient temperature of automobile parts varies in a wide range (e.g., −40 degrees to +120 degrees) and accuracy and precision of current measurement have a huge impact on battery SOC estimation, vehicle energy flow control performance, and fuel efficiency, and the like, and in terms of very tough competition in vehicle fuel efficiency, high accuracy of current measurement needs to be maintained over a change in a large range of ambient temperature and a change in a large range of current amount, but it is difficult to maintain precision of current measurement and linearity according to changes in characteristics of the magnetic core according to temperatures and currents. \hat{5} Unlike industrial applications, vehicles are placed in a severe vibration environment of 5G (gravity acceleration) or higher and the magnetic core may be damaged by vibration or pressure, and here, if the current sensor is broken due to damage of the magnetic core, a current measurement error, a high voltage and low voltage battery SOC estimation error, a vehicle drive motor control error, etc., may occur, and such problems may cause fuel efficiency deterioration, vehicle drivability abnormality due to a drive motor control error, vehicle sudden start, shortening of life due to battery overdischarge, ignition due to battery overcharging, etc, to bring about fatal results to drivers, and in this sense, the current sensor needs to have high reliability and vibration resistance performance, but a use of the magnetic core may be an obstacle to secure reliability vibration resistance performance of the current sensor.

If only the Hall element (magnetic flux measurement unit) without the magnetic core is used, magnetic flux generated by a current is not concentrated by the magnetic core, so that the magnetic flux that passes through the Hall element is significantly reduced, and as a result, signal to noise ratio (SNR) is lowered, which seriously degrades accuracy and precision of current measurement. In addition, the amount of magnetic flux that passes through the Hall element may vary significantly depending on a position of the Hall element, and here, if there is a deviation in the position of the Hall element for each product in a manufacturing process or if the position of the Hall element is changed due to vibration, accuracy of current measurement may be significantly reduced. In addition, when magnetic flux generated by peripheral components, as well as magnetic flux based on the current to be measured, passes through the Hall element, current measurement noise occurs, and as a result, a shield member should be additionally provided to improve the SNR and accuracy of current measurement.

### DISCLOSURE

### Technical Problem

An object of the present disclosure is to provide a coreless contactless current measurement system without a magnetic core in a non-contact current measurement system.

Another object of the present disclosure is to reduce a weight of a current measurement system by not employing a heavy magnetic core.

Another object of the present disclosure is to reduce a size of a current measurement system by not employing a bulky magnetic core.

Another object of the present disclosure is to extend a range of a magnitude of a measurement current by not employing a magnetic core itself, which is saturated by a large current.

Another object of the present disclosure is to reduce a material cost of a current measurement system by not employing a magnetic core that has a large share of the material cost of the current measurement system.

Another object of the present disclosure is to prevent a degradation of measurement accuracy and precision due to a change in temperature by not employing a magnetic core itself having characteristics that change with temperature.

Another object of the present disclosure is to improve current measurement linearity by not employing a magnetic core itself having characteristics that change according to a temperature or the amount of current.

Another object of the present disclosure is to improve vibration resistance and reliability of a current measurement system by not employing a magnetic core itself, which may be damaged by vibration or pressure.

Another object of the present disclosure is to prevent an occurrence of a problem of a degradation of current measurement accuracy and precision due to a reduction in magnetic flux that passes through a magnetic flux measurement unit (Hall element) by not employing a magnetic core serving to concentrate magnetic flux generated by a current.

Another object of the present disclosure is to increase an amount of magnetic flux that passes through a magnetic flux measurement unit by changing only a shape of a conductive unit near the magnetic flux measurement unit without employing a magnetic core.

Another object of the present disclosure is to improve a signal-to-noise ratio (SNR) of a magnetic flux measurement unit by increasing an amount of magnetic flux that passes through the magnetic flux measurement unit.

Another object of the present disclosure is to improve current measurement accuracy by preventing a change in relative positions of a magnetic flux measurement unit and a conductive unit in which a current flows so that a position of the magnetic flux measurement unit is not changed by vibration or the like.

Another object of the present disclosure is to facilitate uniformly maintaining and managing relative positions of a magnetic flux measurement unit, a substrate, and a conductive unit during a manufacturing process and to prevent a change in relative positions of the magnetic flux measurement unit and the conductive unit due to vibration by providing a fixing portion for mounting the magnetic flux measurement unit on the substrate or firmly fixing a position between the magnetic flux measurement unit and the substrate.

Another object of the present disclosure is to reduce an influence of noise due to an external magnetic field by arranging a conductive unit and a magnetic flux measurement unit such that the conductive unit plays a shielding role.

Another object of the present disclosure is not to additionally use a shield member or to provide a minimum shield member by arranging a conductive unit and a magnetic flux measurement unit such that the conductive unit plays a shielding role.

### Technical Solution

In one general aspect, a coreless contactless current measurement system includes: a conductive unit allowing a current to flow therethrough; and a current sensor calculating information on a current flowing through the conductive unit, wherein relative positions of at least a portion of the conductive unit and at least a portion of the current sensor are fixed, and the current sensor acquires magnetic flux generated by the current flowing through the conductive unit and transferred through a non-magnetic material and outputs information on the current flowing through the conductive unit in a wired or wireless manner.

The conductive unit may include a plurality of sub-conductive portions and at least one space portion, the amounts of current flowing through the plurality of sub-conductive portions may be equal, the space portion may be formed between two adjacent sub-conductive portions among the plurality of sub-conductive portions or formed on an inner side surrounded by the plurality of sub-conductive portions and include the non-magnetic material, the current sensor may include at least one magnetic flux measurement unit group, the magnetic flux measurement unit group may include at least one magnetic flux measurement unit, the current sensor may calculate information corresponding to a current amount flowing in the conductive unit based on measurement information from the magnetic flux measurement unit, and at least one magnetic flux measurement unit group may be disposed in the space portion.

One end of any one of the plurality of sub-conductive portions may be connected to one end of another sub-conductive portion adjacent thereto among the plurality of sub-conductive portions, and at least a portion of the conductive unit may include the plurality of sub-conductive portions having a zigzag form.

The space portion may be formed between two adjacent sub-conductive portions among the plurality of sub-conductive portions, and the magnetic flux measurement unit group may be disposed in a central portion of a plane (X-Y plane) connecting the plurality of sub-conductive portions adjacent to the space portion and in a middle portion of the plurality of adjacent sub-conductive portions in a height direction (Z axis direction).

The middle portion in the height direction may be a region within −30% to +30% from a middle point between an uppermost end of the plurality of adjacent sub-conductive portions and a lowermost end thereof.

One end of any one of the plurality of sub-conductive portions may be connected to one end of another sub-conductive portion adjacent thereto, and the plurality of sub-conductive portions may be configured such that at least a portion of the conductive unit has a cylindrical shape or an elliptical column shape.

The space portion may be formed on an inner side surrounded by the plurality of sub-conductive portions, and the magnetic flux measurement unit group may be disposed in a central portion of the cylinder or elliptical column in the space portion and in a middle portion of the cylinder or the elliptical column in a height direction (Z axis direction).

The middle portion in the height direction may be a region within −30% to +30% from a middle point between an uppermost end of the cylinder or the elliptical column and a lowermost end thereof.

The current sensor may include a plurality of magnetic flux measurement units and add up outputs from the magnetic flux measurement units such that a signal-to-noise ratio (SNR) is increased.

The current sensor may include at least one substrate, the substrate may supply the same predetermined current to the magnetic flux measurement unit, and at least some of outputs from the plurality of magnetic flux measurement units may be directly or indirectly combined in series so that the SNR is increased.

The magnetic flux measurement unit group may include n magnetic flux measurement units, a second output terminal of an ith magnetic flux measurement unit and a first output terminal of an (i+1)th magnetic flux measurement unit may be connected, measurement output information of the magnetic flux measurement unit group may be calculated based on a difference between a first output terminal of a first magnetic flux measurement unit and a second output terminal of an nth magnetic flux measurement unit, n may be greater than 1 (n>1), and i may be greater than or equal to 1 and smaller than n (1≤i<n).

The current sensor may include a plurality of magnetic flux measurement unit groups and add up outputs from the magnetic flux measurement unit groups so that an SNR is increased.

The current sensor may further include at least one temperature measurement unit and calculate information corresponding to a current amount flowing through the conductive unit by correcting measurement information from the magnetic flux measurement unit based on output information from the temperature measurement unit.

The conductive unit may include at least one fixing portion, the current sensor may include at least one fixing coupling portion connected to the fixing unit, and at least a portion of the conductive unit and at least a portion of the current sensor may be fixed in relative position by the fixing unit and the fixing coupling unit.

The current sensor may include at least one substrate, the fixing coupling portion may be formed on the substrate, and the fixing portion and the fixing coupling portion may be coupled using at least one of fitting, force fitting, soldering, welding, coupling using a bolt or a nail, bonding using an adhesive, coupling using magnetic force, and coupling using a spring.

The fixing portion may be provided in at least one of an upper surface and a lower surface of the conductive unit, and the substrate may be coupled to at least a portion of the fixing portion.

The fixing portion may be provided on the lower surface of the conductive unit and the substrate may be coupled to the lower surface of the conductive unit, or the fixing portion may be provided on the upper surface of the conductive unit and the substrate may be coupled to the upper surface of the conductive unit.

The magnetic flux measurement unit group or the magnetic flux measurement unit and the substrate may be connected by a conductor for signal transmission and position fixing.

The conductive unit may include at least one fixing portion, the current sensor may include at least one substrate, and the substrate may be fixed by the fixing unit.

The fixing portion may be provided in a middle portion of the conductive unit in a height direction, and the magnetic flux measurement unit may be mounted on the substrate.

The current measurement system may further include: a support unit fixing positions of the conductive unit and the current sensor, wherein at least a portion of the fixing unit may be mechanically connected to at least a portion of the conductive unit and at least a portion of the fixing unit may be mechanically connected to at least a portion of the current sensor so that relative positions of the magnetic flux measurement unit group and the sub-conductive portion are maintained.

### Advantageous Effects

The present disclosure described above has the following effects.

(1) A magnetic core is not employed in the non-contact current measurement system.

(2) A weight of the current measurement system may be reduced by not employing a heavy magnetic core.

(3) A size of the current measurement system may be reduced by not employing a bulky magnetic core.

(4) A range of a magnitude of a measurement current may be extended by not employing the magnetic core itself, which is saturated by a large current.

(5) A material cost of the current measurement system may be reduced by not employing a magnetic core that has a large share of the material cost of the current measurement system.

(6) A degradation of measurement accuracy and precision due to a change in temperature may be prevented by not employing a magnetic core itself having characteristics that change according to temperature.

(7) Current measurement linearity may be improved by not employing a magnetic core itself having characteristics that change according to temperature or an amount of current.

(8) Vibration resistance and reliability of the current measurement system may be improved by not employing a magnetic core itself that may be damaged by vibration or pressure.

(9) A substantial amount of magnetic flux that passes through the magnetic flux measurement unit may be increased by forming the conductive unit near the magnetic flux measurement unit to have a plurality of sub-conductive portions.

(10) Current measurement accuracy and precision may be improved by providing at least one magnetic flux measurement unit group including at least one magnetic flux measurement unit in a center or in a middle portion region where magnetic flux is concentrated and a fringe effect does not occur and directly or indirectly connecting an output from the magnetic flux measurement unit so that a signal-to-noise ratio (SNR) may be improved.

(11) A current measurement error does not occur by vibration by preventing a change in relative positions of a magnetic flux measurement unit and a conductive unit in which a current flows so that a position of the magnetic flux measurement unit is not changed by vibration or the like.

(12) Work convenience may be increased and a mass-production quality deviation may be reduced by facilitating uniformly maintaining and managing relative positions of a magnetic flux measurement unit, a substrate, and a conductive unit during a manufacturing process, and a change in relative positions of the magnetic flux measurement unit and the conductive unit due to vibration may be prevented by providing a fixing unit for mounting the magnetic flux measurement unit on the substrate or firmly fixing a position between the magnetic flux measurement unit and the substrate.

(13) An influence of noise due to an external magnetic field may be reduced by arranging a conductive unit and a magnetic flux measurement unit such that the conductive unit plays a shielding role.

(14) An external noise magnetic field applied in a horizontal direction (X-Y plane) may be naturally shielded by disposing the magnetic flux measurement unit in the central portion between the sub-conductive portion of the conductive unit.

(15) An external noise magnetic field applied in the horizontal direction (X-Y plane) may be naturally shielded by disposing the magnetic flux measurement unit in the central portion surrounded by the sub-conductive portion of the conductive unit.

(16) A shield member may not be additionally used or a minimum shield member may be provided by arranging the conductive unit and the magnetic flux measurement unit such that the conductive unit plays a shielding role.

### BRIEF DESCRIPTION OF THE FIGURES

Features, technical and industrial importance of exemplary embodiments of the present disclosure will be described below with reference to the accompanying drawings, in which like reference numerals designate like elements.

FIG. 1 shows an example of a current sensor having a magnetic core of the prior art.

FIG. 2 shows a configuration example of a proposed current measurement system.

FIG. 3A is a plan perspective view of a conductive unit 100 of a first embodiment of a proposed current measurement system.

FIG. 3B is a bottom perspective view of the conductive unit 100 of the first embodiment of a proposed current measurement system.

FIG. 3C is a plan view of the conductive unit 100 of the first embodiment of a proposed current measurement system.

FIG. 3D is a bottom view of the conductive unit 100 of the first embodiment of a proposed current measurement system.

FIG. 3E is a front view of the conductive unit 100 of the first embodiment of a proposed current measurement system.

FIG. 4A is a plan view of the first embodiment of a proposed current measurement system.

FIG. 4B is a plan view of an example of a magnetic flux distribution of the first embodiment of a proposed current measurement system.

FIG. 4C is a front view of the first embodiment of a proposed current measurement system.

FIG. 4D is a simulation example of a magnetic flux distribution in a front view of the first embodiment of a proposed current measurement system.

FIG. 4E is an example of a combination of the conductive unit 100 and a substrate 220 on a bottom view of the first embodiment of a proposed current measurement system.

FIG. 5A is a plan perspective view of the conductive unit 100 of a second embodiment of a proposed current measurement system.

FIG. 5B is a front view of the conductive unit 100 of the second embodiment of a proposed current measurement system.

FIG. 6A is a front view of the second embodiment of a proposed current measurement system.

FIG. 6B is a bottom view (A-A′ plane) of the second embodiment of a proposed current measurement system.

FIG. 7A is a plan perspective view of the conductive unit 100 of a third embodiment of a proposed current measurement system.

FIG. 7B is a plan view of the conductive unit 100 of the third embodiment of a proposed current measurement system.

FIG. 8A is a bottom view (A-A′ plane) of the third embodiment of a proposed current measurement system.

FIG. 8B is a front view of the third embodiment of a proposed current measurement system.

FIG. 9A is a plan perspective view of a fourth embodiment of a proposed current measurement system.

FIG. 9B is a bottom perspective view of the fourth embodiment of a proposed current measurement system.

FIG. 9C is a front view of the fourth embodiment of a proposed current measurement system.

FIG. 9D is a bottom view of the fourth embodiment of a proposed current measurement system.

FIG. 10A is a plan perspective view of a fifth embodiment of a proposed current measurement system.

FIG. 10B is a bottom view of the fifth embodiment of a proposed current measurement system.

FIG. 10C is a front view of the fifth embodiment of a proposed current measurement system.

FIG. 11A is a plan perspective view of a sixth embodiment of a proposed current measurement system.

FIG. 11B is a front view of the sixth embodiment of a proposed current measurement system.

FIG. 11C is a plan perspective view of a seventh embodiment of a proposed current measurement system.

FIG. 12 is an embodiment in which the plurality of proposed magnetic flux measurement units (Hall A to D) are combined in series using an OP-amplifier circuit.

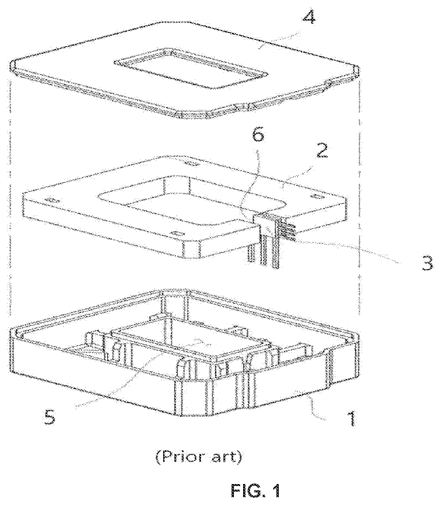

### DETAILED DESCRIPTION

### Best Mode

The aforementioned objects and features of the present disclosure will become more apparent through the following embodiments with respect to the accompanying drawings.

Specific structures and functions stated in the following embodiments of the present disclosure are exemplified to illustrate embodiments according to the spirit of the present disclosure, and the embodiments according to the spirit of the present invention can be achieved in various ways. Further, the present disclosure should not be construed as being limited to the following embodiments.

The present disclosure may be modified variably and may have various embodiments, examples of which will be illustrated in drawings and described in detail. However, it is to be understood that the present disclosure is not limited to a specific disclosed form, but includes all modifications, equivalents, and substitutions without departing from the scope and spirit of the present disclosure.

Further, in the specification, terms including “first” and/or “second” may be used to describe various components, but the components are not limited to the terms. The terms are used to distinguish one component from another component, and for instance, a first component may be referred to as a second component, and similarly, a second component may be referred to as a first component without departing from the scope according to the spirit of the present disclosure.

It should be understood that when one element is referred to as being “connected to” or “coupled to” another element, it may be connected directly to or coupled directly to another element or be connected to or coupled to another element, having the other element intervening therebetween. On the other hand, it is to be understood that when one element is referred to as being “connected directly to” or “contact directly with” another element, it may be connected to or coupled to another element without the other element intervening therebetween. Expressions for describing relationships between components, that is, “between”, “directly between”, “adjacent to”, and “directly adjacent to” should be construed in the same way.

Terms used in the present specification are used only in order to describe specific exemplary embodiments rather than limit the present disclosure. Singular forms are intended to include plural forms unless the context clearly indicates otherwise. It will be further understood that the terms “comprises” or “have” used in this specification specify the presence of stated features, numerals, steps, operations, components, parts, or a combination thereof, but do not preclude the presence or addition of one or more other features, numerals, steps, operations, components, parts, or a combination thereof.

Unless indicated otherwise, it is to be understood that all the terms used in the specification, including technical and scientific terms have the same meaning as those that are understood by those skilled in the art to which the present disclosure pertains. It should be understood that the terms defined by the dictionary are identical with the meanings within the context of the prior art, and they should not be ideally or excessively formally defined unless the context clearly dictates otherwise.

Hereinafter, embodiments of the present disclosure will be described in detail with reference to the accompanying drawings. In describing the present disclosure, in order to facilitate overall understanding of the present disclosure, the same reference numerals indicate the same members throughout the accompanying drawings.

Hereinafter, a “magnetic flux measurement unit (group)” refers to a magnetic flux measurement unit group or the magnetic flux measurement unit.

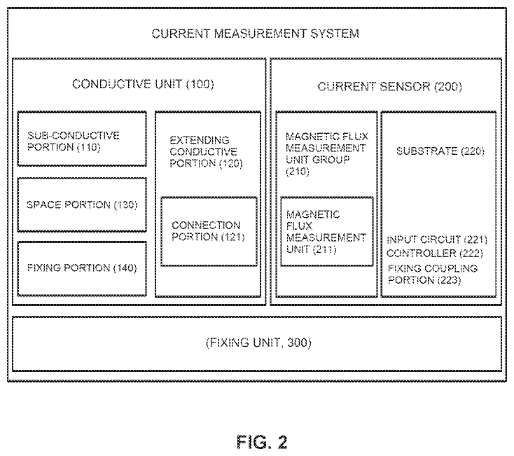

As shown in FIG. 2, a current measurement system includes a conductive unit 100 and a current sensor 200. The conductive unit 100 may include a sub-conductive portion 110, an extending conductive portion 120, and a space portion 130. Here, the sub-conductive portion and the extending conductive portion may be conductors through which current may flow, such as a busbar, an electric wire, etc., and the space portion 130 refers to a space between sub-conductive portions or a space surrounded by the sub-conductive portions. In addition, the conductive unit 100 may include a fixing portion 140 for fixing a relative position of the current sensor 200 and the conductive unit 100. The current sensor 200 may include at least one magnetic flux measurement unit group 210 and may further include an information processing unit 220. The magnetic flux measurement unit group 210 may include at least one magnetic flux measurement unit 211. Here, the magnetic flux measurement unit 211 may be a Hall element using a Hall effect. The substrate 220 may be a relay circuit board that connects the magnetic flux measurement unit 211 and an external device or may be a signal processing substrate reading a signal from the magnetic flux measurement unit 211, calculating corresponding current information, and outputting measured current information in a wired or wireless manner, and in this case, the substrate 220 may further include an input circuit 221, a controller 222, and the like. In addition, the substrate 220 may further include a fixing coupling portion 223 to fix relative positions of the conductive unit and the substrate and the magnetic flux measurement unit. In addition, a separate fixing unit 300 may be provided to fix the relative positions of the conductive unit 100 and the current sensor 200.

### Embodiment 1

As shown in FIGS. 2, 3A to 3E, and 4A to 4C, the current measurement system may include the conductive unit 100 through which a current may flow and the current sensor 200 calculating information on the current flowing through the conductive unit 100. Relative positions of at least a portion of the conductive unit 100 and at least a portion of the current sensor 200 may be fixed, and the current sensor may acquire magnetic flux transferred through a non-magnetic material and output information on the current flowing through the conductive unit 100 in a wired or wireless manner.

In addition, the non-magnetic material may be any one of air, an epoxy, or a resin.

Due to a feature of not using a magnetic material such as ferrite, a weight, a size, and a material cost of the current measurement system may be reduced by not employing a heavy, bulky, and relatively expensive magnetic core. In addition, by not employing a magnetic core itself saturated by a large current, a range of a size of the measurement current may be extended, by not employing a magnetic core itself, which has characteristics that change according to a temperature or an amount of current, a degradation of measurement accuracy and precision due to a change in temperature may be prevented and current measurement linearity may be improved, and by not employing a magnetic core itself, which may be damaged by vibration or pressure, vibration resistance and reliability of the current measurement system may be improved.

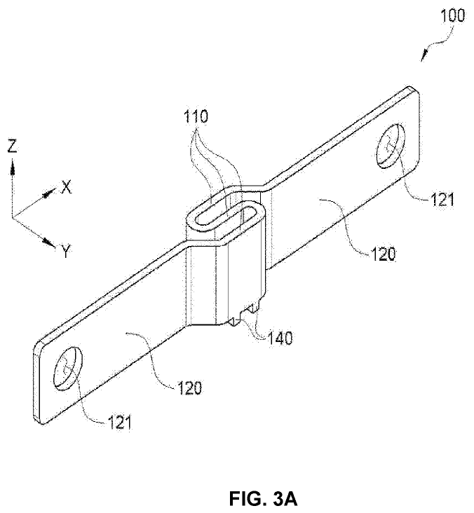

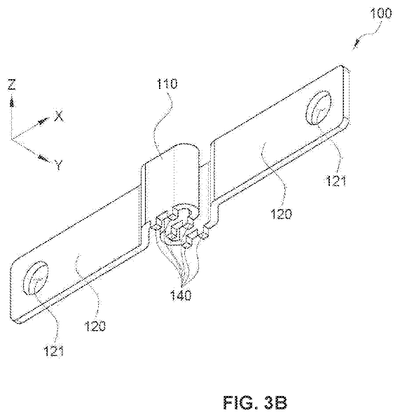

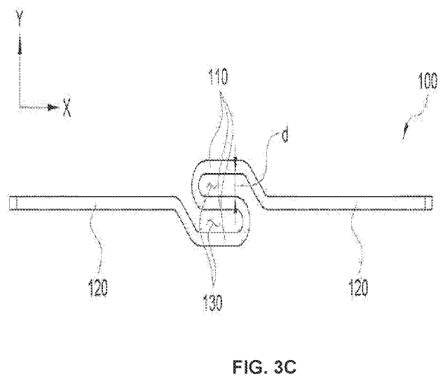

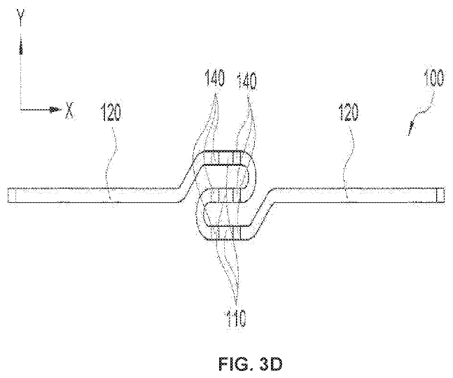

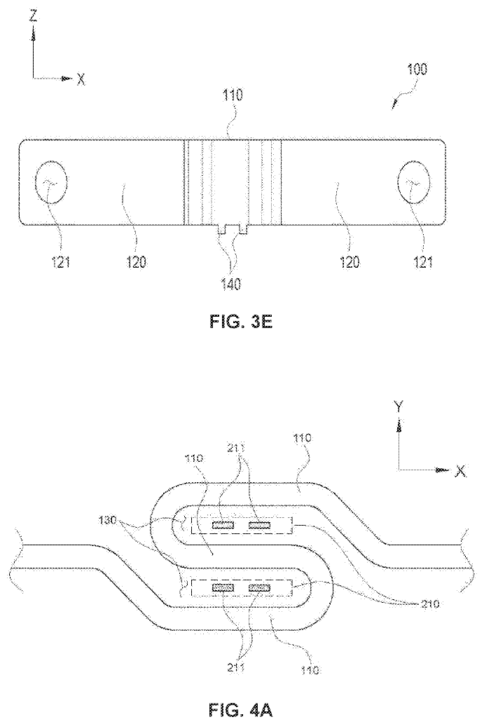

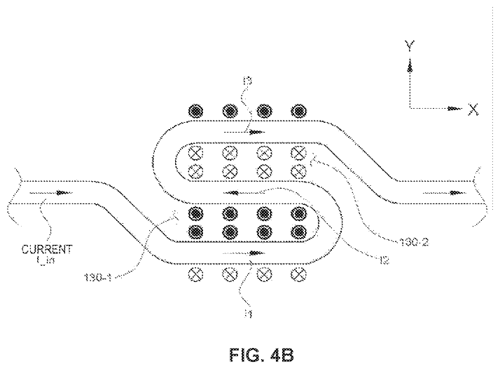

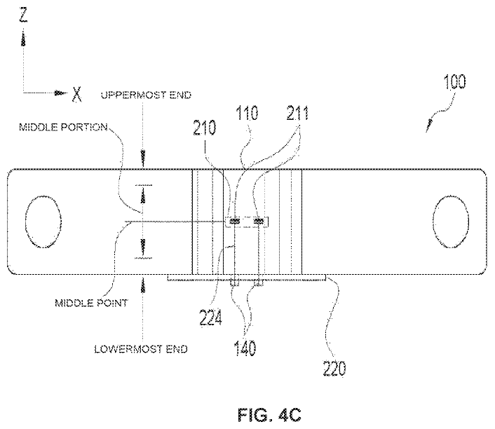

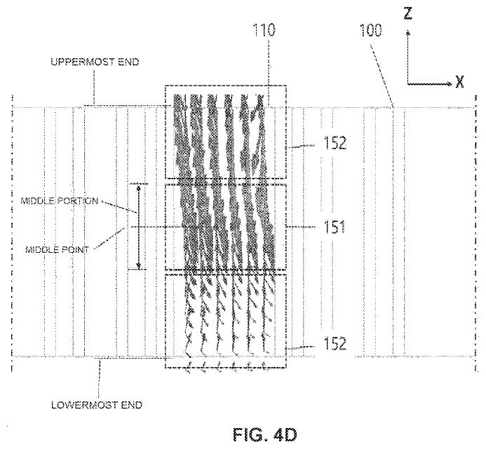

FIGS. 3A to 3E show a conductive unit of a first embodiment, FIGS. 4A and 4C show relative positions of the conductive unit and the magnetic flux measurement unit of the first embodiment, FIGS. 4B and 4D show magnetic flux distribution diagrams, and FIG. 4E shows an example of coupling of the conductive unit 100 and the substrate 220.

The conductive unit 100 includes a plurality of sub-conductive portions 110 and at least one space portion 130, and the amount of current flowing through the plurality of sub-conductive portions 110 is the same. The space portion 130 may be formed between two adjacent sub-conductive portions among the plurality of sub-conductive portions 110 or may be formed on an inner side surrounded by the plurality of sub-conductive portions 110, and may include a non-magnetic material. The current sensor 200 may include at least one magnetic flux measurement unit group 210, and the magnetic flux measurement unit group 210 includes at least one magnetic flux measurement unit 211. The current sensor 200 may calculate information corresponding to the amount of current flowing through the conductive unit 100 based on measurement information from the magnetic flux measurement unit 211, and at least one magnetic flux measurement unit group 210 may be disposed in the space portion 130.

In addition, as shown in FIG. 3A, the sub-conductive portion 110 may be connected to the extending conductive portion 120.

In addition, the extending conductive portion 120 may include a connection portion 121 and may be connected to another conductor through the connection portion 121.

Here, the sub-conductive portion and the extending conductive portion may be a conductor through which current may flow, such as a busbar, an electric wire, etc., and the space portion 130 may be a space between the sub-conductive portions or a space surrounded by the sub-conductive portions.

In addition, when the extending conductive portion 120 is a busbar, the connection portion 121 may be a hole through which a busbar and a busbar or a busbar and a terminal of an electric wire may be connected with bolts and nuts.

In addition, the connection portion 121 may be a connector.

In addition, the connection portion 121 may be connected to another conductor by soldering or welding.

In addition, at least one of the connection portions 121 may be connected to a semiconductor.

In addition, at least one of the connection portions 121 may be connected to an energy storage device such as a battery or a capacitor.

In addition, the connection portions 121 on both sides of the conductive unit 100 may have the same shape or different shapes.

Due to these features, as shown in FIG. 4B, the conductive unit near the magnetic flux measurement unit is formed to have a plurality of sub-conductive portions, thereby increasing the amount of the actual magnetic flux that passes through the magnetic flux measurement unit. In addition, by providing at least one magnetic flux measurement unit group including at least one magnetic flux measurement unit and directly or indirectly connecting an output of the magnetic flux measurement unit in series so that a signal-to-noise ratio (SNR) is improved, current measurement accuracy and precision may be improved.

In addition, relative positions of the conductive unit 100 and the current sensor 200 may be firmly fixed by filling the space 130 using a nonmagnetic material that is solidified such as an epoxy, a resin, and a polymer composite material.

Due to these features, the relative positions of the magnetic flux measurement unit and the conductive unit through which a current flows are not changed so that the position of the magnetic flux measurement unit is not changed by vibration, etc., thereby preventing an occurrence of an error of current measurement due to vibration. In addition, by providing the fixing portion for mounting the magnetic flux measurement unit on the substrate, firmly fixing the positions of the magnetic flux measurement unit and the substrate, and fixing relative positions of the conductive unit and the substrate, uniformly maintaining and managing relative positions of the magnetic measurement unit, the substrate, and the conductive unit during a manufacturing process may be facilitated, whereby work convenience may be increased and a mass-production quality deviation may be reduced, and relative positions of the magnetic flux measurement unit and the conductive unit are not changed by vibration.

The plurality of sub-conductive portions 110 may be configured such that one end of any one thereof is connected to one end of the other sub-conductive portion adjacent thereto and at least a portion of the conductive unit 100 has a zigzag form.

Here, the zigzag form refers to some of ‘ [symbol] ’, ‘ [symbol] ’, ‘ [symbol] ’, ‘ [symbol] ’, ‘Z’ or combinations thereof and refers to an open form, rather than a closed form such as a form of “ [symbol] ” or a cylindrical form. FIGS. 3 and 4 illustrate one example and the claims are not limited to the structure proposed in FIG. 3 or 4.

In addition, current directions of the adjacent sub-conductive portions 110 may be opposite to each other.

These features, as shown in FIG. 4B, have an effect of concentrating double magnetic fluxes on the space portions 130-1 and 130-2 in which the magnetic flux measurement unit group 210 is located because directions in which the current flows through the adjacent sub-conductive portions 100 are opposite to each other. In detail, in FIG. 4B, I_in=I1=I2=I3, and I1 and I2 are in opposite directions and I2 and I3 are in opposite directions, magnetic flux passing through the first space portion 130-1 equal to the sum of magnetic fluxes generated by I1 and I2, and magnetic flux passing through the second space portion 130-2 equals to the sum of magnetic fluxes generated by I2 and I3. Accordingly, the amount of magnetic fluxes passing through the magnetic flux measurement unit may be increased by changing only the shape of the conductive unit near the magnetic flux measurement unit without employing a magnetic core. Furthermore, there is an effect of improving an SNR of the magnetic flux measurement unit by increasing the amount of the magnetic flux that passes through the magnetic flux measurement unit.

As shown in FIGS. 4A and 4C, the space portion 130 may be formed between two adjacent ones of the plurality of sub-conductive portions 110, and the magnetic flux measurement unit group 210 may be disposed in a central portion of a plane (X-Y plane) connecting the plurality of sub-conductive portions 110 adjacent to the space portion 130 and in a middle portion of the plurality of adjacent sub-conductive portions 110 in a height direction (Z axis direction).

In addition, as shown in FIG. 3A, a height h (Z axis direction) of the sub-conductive portion 110 may be greater than a thickness t (XY plane) of the sub-conductive portion 110 (h>t).

A minimum cross-sectional area of the sub-conductive portion 110 is determined by a maximum amount of current, and under a condition that the sub-conductive portion 110 has the same cross-sectional area (i.e., h×t=constant), the height h of the sub-conductive portion 110 increases as the thickness t of the sub-conductive portion 110 is smaller as shown in FIGS. 3A, 3C, and 4A. Also, regarding the adjacent sub-conductive portions 110 bent to be connected, if the thickness t of the sub-conductive portion 110 is large, a bending radius of the adjacent sub-conductive portion may increase, and thus, an interval d (or a width of the space portion 130) between the sub-conductive portions 110 may be reduced as the thickness t of the sub-conductive portion 110 is smaller.

These features have an effect of increasing a magnetic flux density by narrowing the width d of the space portion 130 in which the magnetic flux measurement unit or the magnetic flux measurement unit group exists and increasing accuracy of current measurement due to the increase in the magnetic flux density. Also, since the height h of the space portion 130 in which the magnetic flux measurement unit (group) may exist increases, more magnetic flux measurement units (groups) may be arranged, thereby increasing an SNR. In addition, since the height h of the sub-conductive portion increases, the conductive unit may shield the magnetic flux measurement unit (group) from a magnetic field of external noise approaching in the X-Y plane direction in a wider range. Also, since the width d of the space portion 130 is narrow, a probability that the magnetic field of external noise reaches the magnetic flux measurement unit (group) is reduced, thereby lowering sensitivity of the magnetic flux measurement unit (group) to the magnetic field of external noise.

Here, the middle portion may be an adjacent region including a middle point as shown in FIG. 4C.

As shown in FIG. 4C, the middle portion in the height direction may be a region within −30% to +30% from a middle point between an uppermost end and a lowermost end when a distance between the uppermost end and the lowermost end of the plurality of adjacent sub-conductive portions 110 is 100%.

FIG. 4D is an example of magnetic field analysis. As shown in FIG. 4D, a direction of magnetic flux is not uniform due to a fringe effect in a magnetic flux peripheral portion 152 in a direction toward the uppermost or lowermost end in the height direction, while a magnetic flux is uniformly maintained in a vertical direction (Z axis direction) in a magnetic flux concentration portion 151 as a region within −30% to +30% based on the middle point (i.e., within an area of 20 to 80% in the height direction as an absolute position), and thus, the effect of improving accuracy and precision of magnetic flux measurement may be obtained by disposing the magnetic flux measurement unit group or the magnetic flux measurement unit in the middle portion (or in the magnetic flux concentration portion 151) in the height direction (Z axis direction). In addition, since the height h of the space portion 130 in which the magnetic flux measurement unit (group) may exist is increased, the region of the middle portion or the magnetic flux concentration portion 151 may be increased to arrange more magnetic flux measurement units (groups), and thus, the SNR may be further increased.

In addition, as shown in FIG. 4C, the magnetic flux measurement unit or the magnetic flux measuring group is arranged in the middle portion of the height direction (Z-axis direction) so that the conductive unit and the magnetic flux measurement unit (group) are disposed such that the conductive unit naturally plays a role of shielding partly, thereby obtaining an effect of reducing noise due to an external magnetic field. In detail, the conductive unit, or a conductor, naturally shields a magnetic field of external noise applied in the horizontal direction (X-Y plane). Since the conductive unit and the magnetic flux measurement unit (group) are arranged such that the conductive unit plays a role of shielding, a shield member may not be additionally used or only a minimum shield member may be provided.

As shown in FIGS. 3B, 3D, 3E, 4C, 4E, 5A, 5B, 6A, and 6B, the conductive unit 100 may include at least one fixing portion 140, the current sensor 200 may include at least one fixing coupling portion 223 connected to the fixing portion 140, and as shown in FIG. 4E, relative positions of at least a portion of the conductive unit 100 and at least a portion of the current sensor 200 may be fixed by the fixing portion 140 and the fixing coupling portion 223.

The current sensor 200 may include at least one substrate 220, the fixing coupling portion 223 may be formed at the substrate 220, and the fixing portion 140 and the fixing coupling portion 223 may be coupled using at least one of fitting, force fitting, soldering, welding, coupling using a bolt or a nail, bonding using an adhesive, coupling using magnetic force, and coupling using a spring.

As shown in FIGS. 3A to 3E and 4A to 4C, the fixing portion 140 may be provided on a lower surface of the conductive unit 100 and the substrate 220 may be coupled to the lower surface of the conductive unit 100, or the fixing portion 140 may be provided on an upper surface of the conductive unit 100 and the substrate 220 may be coupled to the upper surface of the conductive unit 100.

As shown in FIG. 4C, the magnetic flux measurement unit group 210 or the magnetic flux measurement unit 211 and the substrate 220 may be coupled with a fixing member 224 for signal transmission and position fixing.

Here, the fixing member 224 is a Hall element chip bridge that is the magnetic flux measurement unit 211 or a conductor connecting an output of the Hall element chip and an input circuit 221 of the substrate 220 or may be a fixing member for fixing a relative position of the magnetic flux measurement unit from the substrate.

In addition, the relative positions of the conductive unit 100 and the current sensor 200 may be firmly fixed by filling the space 130 using an epoxy or a resin as a non-magnetic material.

These features have an effect of improving current measurement accuracy by preventing the relative positions of the magnetic flux measurement unit and the conductive unit through which a current flows so that the position of the magnetic flux measurement unit is not changed by vibration or the like.

These features have an effect of preventing a change in the position of the magnetic flux measurement unit group or magnetic flux measurement unit by the fixing member 224 when the space portion 130 is filled using an epoxy or a resin.

In addition, by providing the fixing portion for mounting the magnetic flux measurement unit (group) on the substrate, firmly fixing positions of the magnetic flux measurement unit (group) and the substrate, and fixing relative positions of the conductive unit and the substrate, uniformly maintaining and managing the relative positions of the magnetic flux measurement unit, the substrate, and the conductive unit during a manufacturing process may be facilitated and the relative positions of the magnetic flux measurement unit (group) and the conductive unit due to vibration may not be changed.

### Embodiment 2

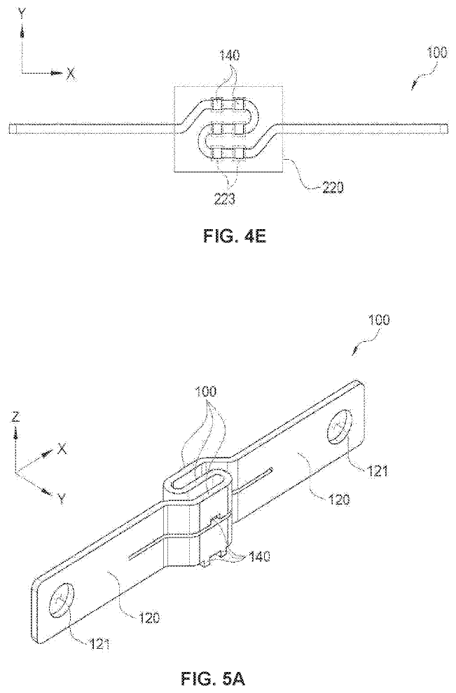

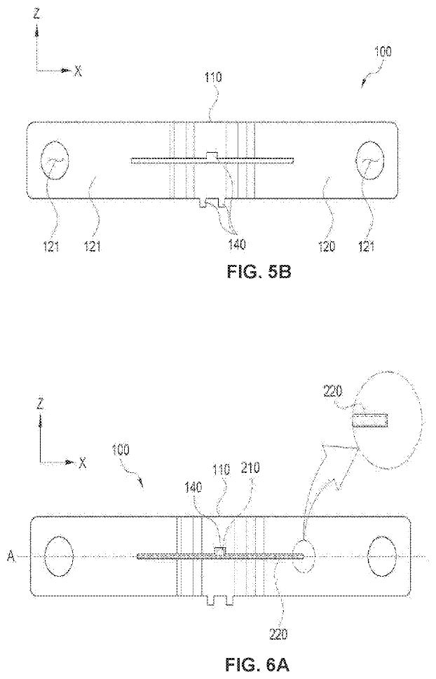

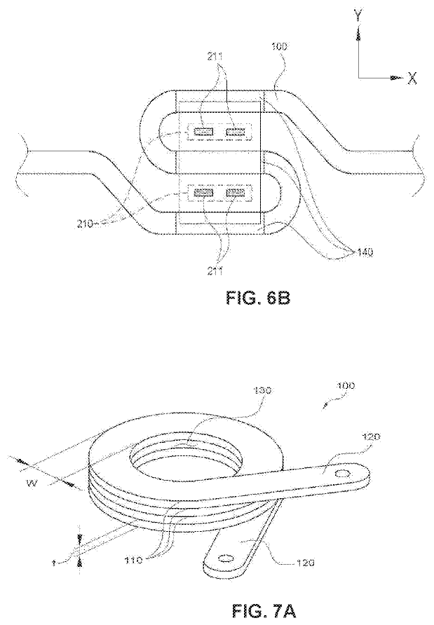

As shown in FIGS. 5 and 6, the conductive unit 100 includes at least one fixing portion 140, the current sensor 200 includes at least one substrate 220, and the substrate 220 may be fixed by the fixing portion 140.

The fixing portion 140 may be provided at a middle portion of the conductive unit 100 in a height direction, and the magnetic flux measurement unit 211 is mounted on the substrate 220.

Here, mounting of the magnetic flux measurement unit on the substrate may refer to soldering a chip type magnetic flux measurement unit on a PCB.

With these features, by placing a position of the fixing portion for fixing the substrate on which the magnetic flux measurement unit (group) is mounted in the middle portion of the conductive unit in the height direction, concentration of magnetic flux may be maintained, and thus, by disposing the magnetic flux measurement unit group 210 within the region, an effect of improving accuracy and precision of magnetic flux measurement may be obtained.

Here, the middle portion in the height direction may be a region within −30% to +30% from a middle point between the uppermost and lowermost ends when a distance between the uppermost and lowermost ends of the plurality of adjacent sub-conductive portions 110 is 100%.

In addition, by disposing the magnetic flux measurement unit (group) in the middle portion, the conductive unit may naturally play a role of shielding, thereby reducing noise due to an external magnetic field.

In addition, by arranging the conductive unit and the magnetic flux measurement unit so that the conductive unit acts as a shield, there is an effect that an additional shielding member is not used or only a minimum shielding member may be provided.

### Embodiment 3

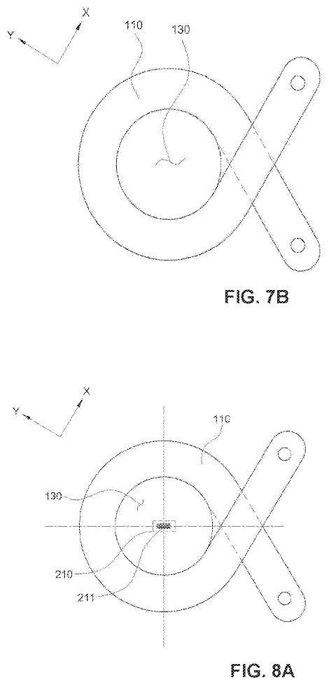

As shown in FIGS. 7 to 11, one end of any one of the plurality of sub-conductive portions 110 is connected to one end of another sub-conductive portion adjacent thereto, and the plurality of sub-conductive portions 110 may be configured such that at least a portion of the conductive unit 100 has a cylindrical shape elliptic cylindrical shape.

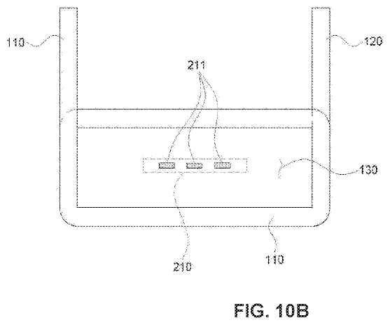

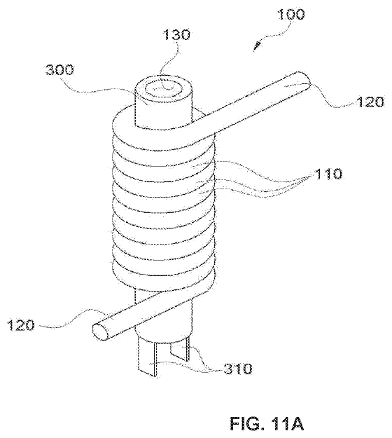

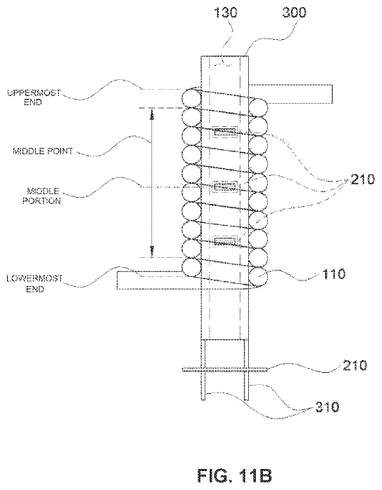

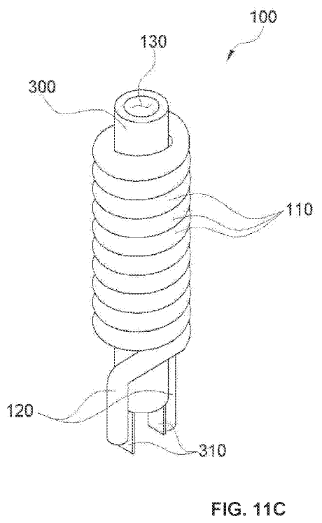

FIG. 7A shows a conductive unit in the form of a cylinder, FIG. 10A shows a conductive unit in the form of an elliptical column, and FIGS. 11A and 11C are conductive units in the form of a cylinder or an elliptical column using a conducting wire.

Here, at least a portion of the conductive unit and the sub-conductive portion may be a conductor through which current may flow, such as a busbar or an electric wire.

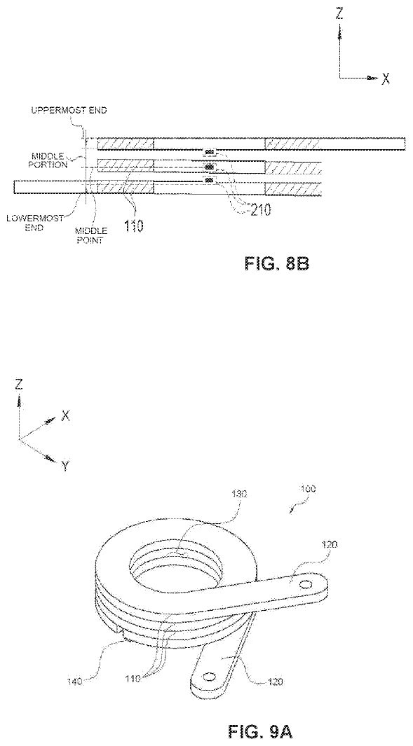

In some embodiments, these features are more capable of facilitating manufacture compared with the zigzag form presented above. In more detail, the cylindrical shape may be easily and quickly manufactured by a circular bending device. In addition, as may be seen by comparing FIGS. 8A and 10B, a current measurement SNR may be improved in that the elliptic cylindrical shape secures a space on the X-Y plane in which one magnetic flux measurement means group includes more magnetic flux measurement unit, compared with the cylindrical shape. In addition, FIGS. 11A and 11C have an effect that may be easily manufactured manually using a conducting wire.

In addition, as shown in FIGS. 7A and 10A, a height or thickness (t, Z-axis direction) of the sub-conductive portion 110 may be smaller than a width (w, X-Y plane) of the sub-conductive portion 110 (t<w).

These features have the effect of increasing a magnetic flux density in the space portion 130 in which the magnetic flux measurement unit or the magnetic flux measurement unit group exists, and the conductive unit forms a cylindrical or elliptical column shape in the horizontal plane (X-Y plane) and may partly play a role of shielding.

In addition, as shown in FIG. 11A, the conductive unit 100 having a cylindrical or elliptical column shape is formed by winding a conducting wire around the fixing unit 300. By winding the conducting wire around the fixing unit 300, it is easy to uniformly manufacture the shape of the conductive unit 100 formed of the conducting wire and to maintain the shape.

As shown in FIGS. 7A, 7B, 8A, 8B, 10B, 10C, 11A, and 11C, the space portion 130 is formed on the inner side surrounded by the plurality of sub-conductive portions 110 and the magnetic flux measurement unit group 210 may be disposed in a central portion of the cylinder or elliptical column in the space portion 130 and in a middle portion of the cylinder or elliptical column in the height direction (Z-axis direction).

As shown in FIGS. 8B, 10C, and 11B, the middle portion in the height direction may be a region within −30% to +30 from a middle point between the uppermost end and the lowermost end of the cylinder or the elliptical column when a distance between the uppermost end and the lowermost end is 100%.

With these features, concentration of magnetic flux is lowered due to a fringe effect in a direction toward the uppermost end or lowermost end in the height direction, while concentration of magnetic flux is maintained in the region of −30% to +30% from the middle point as a center, that is, 20 to 80% in the height direction as an absolute position, and thus, accuracy and precision of magnetic flux measurement may be improved by arranging the magnetic flux measurement unit group 210 in the region. When the plurality of sub-conductive portions 110 are configured so that at least a portion of the conductive unit 100 has a cylindrical or elliptical column shape, a height (Z-axis direction) of the sub-conductive portion 110 is smaller a width (X-Y plane) of the sub-conductive portion 110, thereby maximizing such an effect.

With these features, as shown in FIGS. 8B, 10C, and 11B, by arranging the magnetic flux measurement unit in the central portion surrounded with the sub-conductive portion of the conductive unit, an external noise magnetic field applied in the horizontal direction (X-Y plane) may be naturally shielded. In more detail, the conductive unit, as a conductor, may naturally shield at least partly the external noise magnetic field applied in the horizontal direction (X-Y plane). By arranging the conductive unit and the magnetic flux measurement unit so that the conductive unit serves as a shield, an additional shielding member may not be used or only a minimum shielding member may be provided.

### Embodiment 4

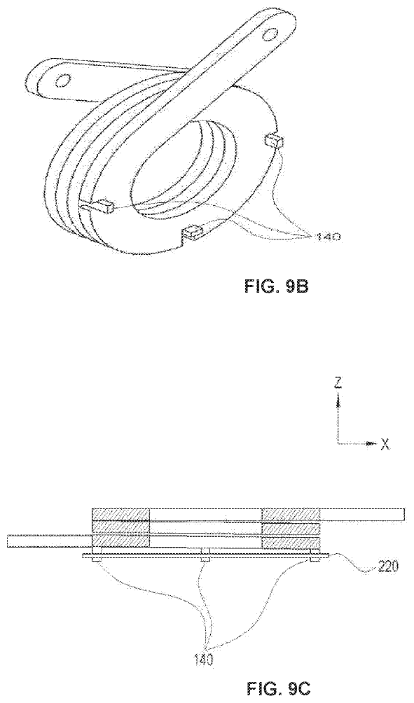

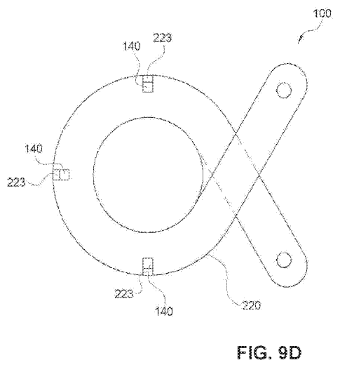

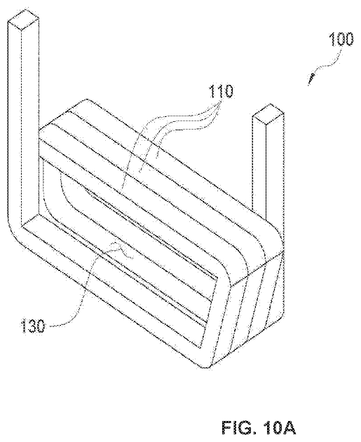

In addition, when the plurality of sub-conductive portions 110 are configured so that at least a portion of the conductive unit 100 has a cylindrical or elliptical column shape, the fixing portion 140 may be configured by bending at least a portion of the lowermost or uppermost sub-conductive portion 110 as shown in FIGS. 9A to 9D. The fixing portion 140 may be coupled to the fixing coupling portion 223 of the substrate 220. As shown in FIG. 9C, the substrate 220 may be disposed at a lower end or an upper end of the conductive unit 100, and the fixing coupling portion 223 of the substrate 220 and the fixing portion 140 of the conductive unit 100 may be coupled by at least one of fitting, force fitting, soldering, welding, coupling using a bolt or a nail, bonding using an adhesive, coupling using magnetic force, and coupling using a spring.

In addition, as shown in FIGS. 11A and 11C, in the case of a conductive unit in a cylindrical or an elliptical column shape using a conducting wire, the fixing portion 310 is provided on at least a portion of the separate fixing unit 300 as shown in FIG. 11B. The fixing portion 310 may be coupled to the fixing coupling portion 223 of the substrate 220. As shown in FIG. 11B, the substrate 220 may be disposed at a lower end or an upper end of the conductive unit 100, and the fixing coupling portion 223 of the substrate 220 and the fixing portion 310 of the fixing unit 300 may be coupled using at least one of fitting, force fitting, soldering, welding, coupling using a bolt or a nail, bonding using an adhesive, coupling using magnetic force, and coupling using a spring.

### Embodiment 5

As shown in FIGS. 4A, 6B, 8B, 10B, 10C, and 11B, the current sensor 200 includes a plurality of the magnetic flux measurement units 211 and adds up outputs from the magnetic flux measurement units 211 as the SNR increases.

The current sensor 200 includes at least one substrate 220, the substrate 220 supplies the same predetermined current to the magnetic flux measurement unit 211, and outputs from the plurality of magnetic flux measurement units are directly or indirectly coupled in series to increase the SNR.

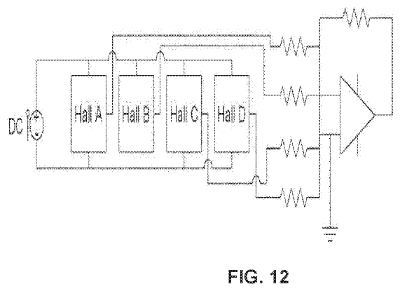

FIG. 12 shows an embodiment in which a plurality of magnetic flux measurement units (Hall A to D) is coupled in series using an OP-amplifier circuit.

Due to these features, by directly or indirectly connecting the outputs from the magnetic flux measurement units in series to improve the SNR, there is an effect of improving current measurement accuracy and precision.

The magnetic flux measurement unit group 210 includes n magnetic flux measurement units 211. A second output terminal of an ith magnetic flux measurement unit and a first output terminal of an (i+1)th magnetic flux measurement unit may be directly or indirectly connected, and measurement output information of the magnetic flux measurement unit group 210 may be calculated based on a potential difference between a first output terminal of a first magnetic flux measurement unit and a second output terminal of an nth magnetic flux measurement unit, n may be greater than 1 (n>1), and 1 may be equal to or greater than 1 and smaller than n (1≤i<n). Here, indirectly connecting the output terminals refers to connecting the output terminals using an OP-amplifier circuit.

### Embodiment 6

The current sensor 200 includes a plurality of the magnetic flux measurement unit groups 210 adds up outputs from the magnetic flux measurement unit groups 210 to increase an SNR.

Here, adding up the outputs from the magnetic flux measurement unit groups 211 is includes connecting outputs from the magnetic flux measurement units 211 included in the plurality of magnetic flux measurement unit groups 210 directly or indirectly in series, as well as adding up the outputs from the magnetic flux measurement units 211 included in the plurality of magnetic flux measurement unit groups 210 using the OP-amplifier circuit.

Due to these features, by directly or indirectly connecting the outputs from the magnetic flux measurement units included in the plurality of magnetic flux measurement unit groups in series to improve the SNR, current measurement accuracy and precision may be further improved.

### Embodiment 7

The current sensor 200 further includes at least one temperature measurement unit. The current sensor corrects measurement information from the magnetic flux measurement unit 211 based on output information from the temperature measurement unit and calculates information corresponding to an amount of current flowing through the conductive unit 100.

With these features, by not employing a magnetic core itself having characteristics changing according to temperature and considering even the characteristics of the magnetic flux measurement unit 211 changing according to temperature, a degradation of measurement accuracy and precision due to a change in temperature may be prevented and current measurement linearity may be improved.

### Embodiment 8

The conductive unit 100 and the fixing unit 300 for fixing a position of the current sensor 200 are provided, and at least a portion of the fixing unit 300 is mechanically connected to at least a portion of the conductive unit 100 and at least a portion of the fixing unit 300 may be mechanically connected to at least a portion of the current sensor 200.

Here, a support unit may be plastics, a resin, an epoxy, a polymer compound, a non-magnetic material, or the like.

### Embodiment 9

In all the embodiments presented above, an electric insulation unit may be provided between the conductive unit 100 and the substrate 220. The electrical insulation unit may include at least one of an air gap, a structure using an insulating material, an insulating film, or an insulating paper.

Due to these features, there is an effect of preventing damage to the substrate or an error in current measurement due to a potential difference between the conductive unit and the substrate.

### Embodiment 10

In all the embodiments presented above, a thermal insulation unit may be provided between the conductive unit 100 and the substrate 220. The thermal insulation unit may include at least one of an air gap and a thermal insulator.

Due to these features, there is an effect of preventing heat from the conductive unit from being transferred to the substrate to reduce life or durability of the substrate or to interfere with a normal operation of the components provided on the substrate.

### Embodiment 11

In all the embodiments presented above, at least a portion of an electromagnetic wave shielding unit may be provided between the conductive unit 100 and the substrate 220.

Due to these characteristics, magnetic flux or a magnetic field due to a current flowing through the conductive unit may be at least partly prevented from affecting a circuit provided in the substrate to degrade current signal measurement performance, rather than affecting only the magnetic flux measurement unit (group).

### Embodiment 12

In all of the embodiments presented above, the substrate 220 may include a signal connector or a signal terminal for inputting/outputting signals.

In addition, when there is a conductive unit in a direction of one surface of the substrate 220 (for example, in a positive direction of the Z-axis), a signal connector or a terminal may be provided in a direction of the other surface of the substrate (in a negative direction of the Z-axis).

Here, the signal output connector or the terminal may be provided on the other surface of the substrate and the X-Y axis direction may be a certain direction. That is, the signal connector or the signal terminal may be provided in a certain direction in the X-Y axis on the other surface of the substrate (in the negative direction of Z-axis).

Due to these features, there is an effect of at least partially preventing a magnetic flux or a magnetic field due to a current flowing through the conductive unit from adversely affecting the signal connector, the signal terminal, and a signal line for transmitting current measurement information.

### Embodiment 13

For application to a vehicle with a lot of vibration, the conductive unit 100 may have the fixing portion 140 provided at each of an upper portion and a lower portion (not shown) to fix a position of the conductive unit 100, a position of the current sensor 200, relative positions of the conductive unit and the current sensor, or a position of the current measurement system including the conductive unit and the current sensor. In detail, as an embodiment, in FIG. 3A, the conductive unit 100 includes the fixing portion 140 only on the lower surface of the conductive unit, but the same type of fixing portion may also be provided on the upper surface of the conductive unit, one of the fixing portions on the upper surface and the lower surface may be coupled to at least the current sensor, and the other may be coupled to a structure such as a fixing unit, a case, etc. In the embodiment of the conductive unit shown in FIGS. 9A and 10A, as in the above, the fixing portion 140 may be provided on both the upper and lower surfaces, similarly.

It will be obvious to those skilled in the art to which the present disclosure pertains that the present disclosure described above is not limited to the above-mentioned exemplary embodiments and the accompanying drawings, but may be variously substituted, modified, and altered without departing from the scope and spirit of the present disclosure.

### DETAILED DESCRIPTION OF MAIN ELEMENTS

1: case
2: core
3: PCB
4: cover
5: through hole
6: hall sensor
100: conductive unit
110: sub-conductive portion
120: extending conductive portion
121: connection portion
130: space portion
140: fixing portion
151: magnetic flux concentration portion
152: magnetic flux periphery portion
200: current sensor
210: magnetic flux measurement unit group
211: magnetic flux measurement unit
220: substrate
221: input circuit
222: controller
223: fixing coupling portion
224: fixing member
300: fixing unit
310: fixing portion

1. A coreless contactless current measurement system comprising:
a conductive unit allowing a current to flow there through; and
a current sensor calculating information on a current flowing through the conductive unit,
wherein relative positions of at least a portion of the conductive unit and at least a portion of the current sensor are fixed, and
the current sensor acquires magnetic flux generated by the current flowing through the conductive unit and transferred through a non-magnetic material and outputs information on the current flowing through the conductive unit in a wired or wireless manner.

2. The coreless contactless current measurement system of claim 1, wherein
the conductive unit includes a plurality of sub-conductive portions and at least one space portion,
the amounts of current flowing through the plurality of sub-conductive portions are equal,
the space portion is formed between two adjacent sub-conductive portions among the plurality of sub-conductive portions or formed on an inner side surrounded by the plurality of sub-conductive portions and includes the non-magnetic material,
the current sensor includes at least one magnetic flux measurement unit group,
the magnetic flux measurement unit group includes at least one magnetic flux measurement unit,
the current sensor calculates information corresponding to a current amount flowing in the conductive unit based on measurement information from the magnetic flux measurement unit, and
at least one magnetic flux measurement unit group is disposed in the space portion.

3. The coreless contactless current measurement system of claim 2, wherein
one end of any one of the plurality of sub-conductive portions is connected to one end of another sub-conductive portion adjacent thereto among the plurality of sub-conductive portions, and
at least a portion of the conductive unit includes the plurality of sub-conductive portions having a zigzag form.

4. The coreless contactless current measurement system of claim 3, wherein
the space portion is formed between two adjacent sub-conductive portions among the plurality of sub-conductive portions, and
the magnetic flux measurement unit group is disposed in a central portion of a plane connecting the plurality of sub-conductive portions adjacent to the space portion and in a middle portion of the plurality of adjacent sub-conductive portions in a height direction.

5. The coreless contactless current measurement system of claim 4, wherein
the middle portion in the height direction is a region within −30% to +30% from a middle point between an uppermost end of the plurality of adjacent sub-conductive portions and a lowermost end thereof.

6. The coreless contactless current measurement system of claim 2, wherein
one end of any one of the plurality of sub-conductive portions is connected to one end of another sub-conductive portion adjacent thereto, and
the plurality of sub-conductive portions are configured such that at least a portion of the conductive unit has a cylindrical shape or an elliptical column shape.

7. The coreless contactless current measurement system of claim 6, wherein
the space portion is formed on an inner side surrounded by the plurality of sub-conductive portions, and
the magnetic flux measurement unit group is disposed in a central portion of the cylinder or elliptical column in the space portion and in a middle portion of the cylinder or the elliptical column in a height direction (Z axis direction).

8. The coreless contactless current measurement system of claim 7, wherein
the middle portion in the height direction is a region within −30% to +30% from a middle point between an uppermost end of the cylinder or the elliptical column and a lowermost end thereof.

9. The coreless contactless current measurement system of claim 2, wherein
the current sensor includes a plurality of magnetic flux measurement units and adds up outputs from the magnetic flux measurement units such that a signal-to-noise ratio (SNR) is increased.

10. The coreless contactless current measurement system of claim 9, wherein
the current sensor includes at least one substrate,
the substrate supplies a predetermined current to the magnetic flux measurement unit, and
at least some of outputs from the plurality of magnetic flux measurement units are directly or indirectly combined in series so that the SNR is increased.

11. The coreless contactless current measurement system of claim 10, wherein
the magnetic flux measurement unit group includes n magnetic flux measurement units,
a second output terminal of an ith magnetic flux measurement unit and a first output terminal of an (i+1)th magnetic flux measurement unit are connected directly or through a circuit,
measurement output information of the magnetic flux measurement unit group is calculated based on a difference between a first output terminal of a first magnetic flux measurement unit and a second output terminal of an nth magnetic flux measurement unit,
n is greater than 1 (n>1), and i is greater than or equal to 1 and smaller than n (1≤i<n).

12. The coreless contactless current measurement system of claim 9, wherein
the current sensor includes a plurality of magnetic flux measurement unit groups and adds up outputs from the magnetic flux measurement unit groups so that an SNR is increased.

13. The coreless contactless current measurement system of claim 12, wherein
the current sensor further includes at least one temperature measurement unit and calculates information corresponding to a current amount flowing through the conductive unit by correcting measurement information from the magnetic flux measurement unit based on output information from the temperature measurement unit.

14. The coreless contactless current measurement system of claim 2, wherein
the conductive unit includes at least one fixing portion,
the current sensor includes at least one fixing coupling portion connected to the fixing unit, and
at least a portion of the conductive unit and at least a portion of the current sensor are fixed in relative position by the fixing unit and the fixing coupling unit.

15. The coreless contactless current measurement system of claim 14, wherein
the current sensor includes at least one substrate,
the fixing coupling portion is formed at the substrate, and
the fixing portion and the fixing coupling portion are coupled using at least one of fitting, force fitting, soldering, welding, coupling using a bolt or a nail, bonding using an adhesive, coupling using magnetic force, and coupling using a spring.

16. The coreless contactless current measurement system of claim 15, wherein
the fixing portion is provided in at least one of an upper surface and a lower surface of the conductive unit, and
the substrate is coupled to at least a portion of the fixing portion.

17. The coreless contactless current measurement system of claim 16, wherein
the magnetic flux measurement unit group or the magnetic flux measurement unit and the substrate are connected by a conductor for signal transmission and position fixing.

18. The coreless contactless current measurement system of claim 2, wherein
the conductive unit includes at least one fixing portion,
the current sensor includes at least one substrate, and
the substrate is fixed by the fixing unit.

19. The coreless contactless current measurement system of claim 16, wherein
the fixing portion is provided in a middle portion of the conductive unit in a height direction, and
the magnetic flux measurement unit is mounted on the substrate.

20. The coreless contactless current measurement system of claim 2, further comprising:
a fixing unit fixing positions of the conductive unit and the current sensor,
wherein at least a portion of the fixing unit is mechanically connected to at least a portion of the conductive unit and at least a portion of the fixing unit is mechanically connected to at least a portion of the current sensor so that relative positions of the magnetic flux measurement unit group and the sub-conductive portion are maintained.
